(19) United States
(12) Patent Application Publication
(10) Pub. No.: US 2012/0091343 A1
(43) Pub. Date: Apr. 19, 2012

(54) DEVICE FOR DETECTING ELECTROMAGNETIC RADIATION WITH POLARIZED BOLOMETRIC DETECTOR, AND APPLICATION FOR INFRARED DETECTION

(75) Inventors: Gaelle Repellin, Meaudre (FR); Gilles Chammings, Grenoble (FR); Michael Tchagaspanian, Saint Ismier (FR)

(73) Assignee: COMMISSARIAT A L'ENERGIE ATOMIQUE ET AUX ENE ALT, Paris (FR)

(21) Appl. No.: 13/376,487

(22) PCT Filed: Jun. 7, 2010
(86) PCT No.: PCT/FR10/51121

§ 371 Date: Dec. 6, 2011

(30) Foreign Application Priority Data
Jun. 15, 2009 (FR) 0953974

(51) Int. Cl. H01L 27/144; G01J 5/10

(52) U.S. Cl. 250/338.4; 250/349

(57) ABSTRACT

A device for detecting electromagnetic radiation, including pixels each detecting a radiation and providing an electric current representative of the detected radiation, a column to which the pixels are connected, and transmitting the electric currents provided by the pixels, and an electrical module, to which the transmission column is connected, processing the electric currents provided by the pixels. Each pixel includes a detection circuit including a bolometric detector connected in series to a voltage polarization device of the bolometric detector for adjusting the electric current supplied to the processing module by the transmission column. A current polarization circuit of the bolometric detector adjusts the electric current supplied to the electrical processing module by the transmission column, the current polarization circuit being different from the detection circuit and being connected to the bolometric detector at one point in the detection circuit located between the bolometric detector and the voltage polarization device.

This invention relates to a device for detecting electromagnetic radiation and its use for infrared detection.

However, although more clearly described in connection with the detection of infrared radiation by use of an infrared imager, it is also applicable to the domain of detecting other radiation, such as visible or ultraviolet radiation.

The invention more specifically relates to a device for detecting electromagnetic radiation comprising at least one pixel for detecting radiation to provide an electric current representative of the detected radiation, the pixel comprising a detection circuit including a bolometric detector connected in series with voltage polarisation means.

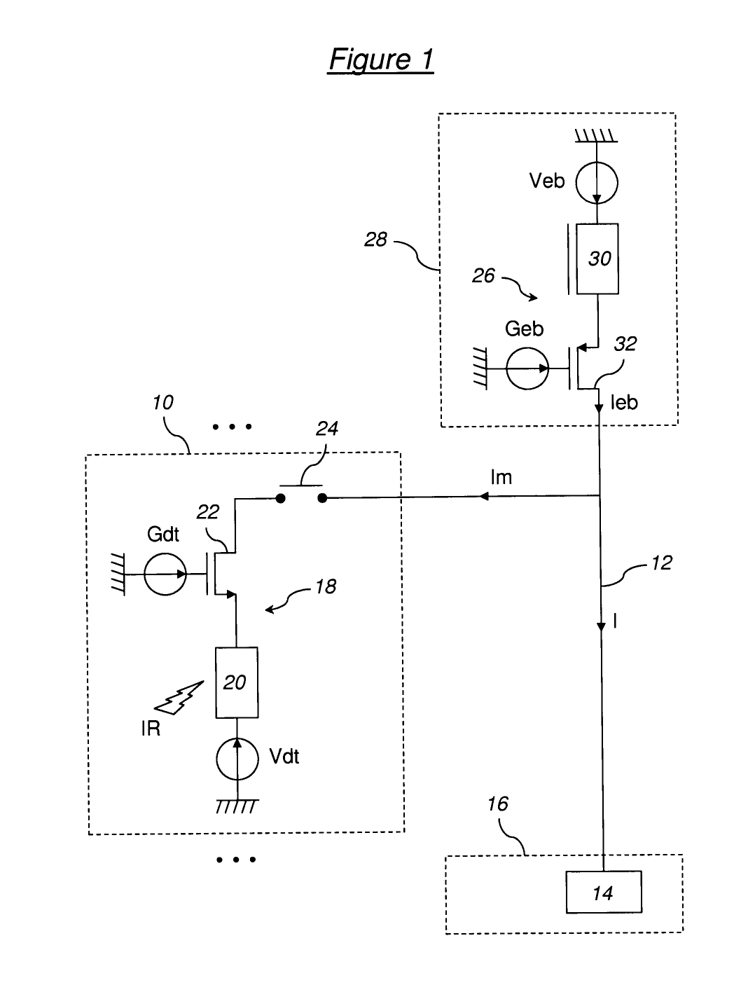

Such a device is illustrated schematically in FIG. 1 in the case of an infrared line imager. A similar real world example is also disclosed in the French patent application published under number FR 2 848 666.

In general, it comprises an array of sensors, or pixels, arranged in rows and columns. In FIG. 1, only one pixel 10 is shown for simplicity. It is connected to an electrical current transmission column 12 common to a column of pixels. This transmission column 12 is connected to a module 14 for sequentially processing electric currents provided by the pixels of the column in question and transmitted by the column 12, for displaying a raster image resulting from the detection of electromagnetic radiation IR by each of the pixels. This processing module 14 is located in a bottom of column circuit 16.

More specifically, the processing carried out by the module 14 consists of integrating the electric current received from the pixel 10 by means of an integrator circuit. The result of the integration is supplied in the form of voltage. It is this voltage that then contains the information supplied by the pixel 10. This voltage is then sent on a bus that sequentially retrieves all of the voltages associated with all of the pixels of the array of the detection device. This sequence of values associated with the pixels is then transmitted to a video amplifier to ultimately reconstitute and display an image representative of the detected electromagnetic radiation.

The pixel 10 is a sensor that comprises an electronic circuit 18 for detecting electromagnetic radiation. In the context of infrared imaging, this detection circuit 18 usually includes an uncooled microbolometric detector 20 connected in series with a transistor 22 for voltage polarisation of this microbolometric detector 20. The transistor 22 is generally a MOS field-effect transistor, more specifically an n-type transistor in the example in FIG. 1, voltage generator mounted to allow for the acquisition and processing of an electric current supplied by the microbolometric detector 20.

Indeed, the microbolometric detector 20 is a sensor that reacts to temperature changes by changing its electrical resistance around a mean value that depends on one of the materials it comprises. By application of Ohm's law, its voltage polarisation therefore allows it to cause a variation in an electric current that passes through it based on temperature changes of a scene submitted to the imager, around a mean value defined by the polarisation.

Traditionally, an uncooled microbolometric detector includes the following items:
means of absorbing an electromagnetic radiation IR to be converted into heat,
means of thermally insulating the detector, allowing it to become warm, and
a temperature variable resistive element.

The potential of one terminal of the microbolometric detector 20 is set to a value Vdt. Thus, the voltage polarisation of the microbolometric detector 20 by the n-MOS transistor 22 is controlled by the gate voltage Gdt of this transistor, which is connected to another terminal of the microbolometric detector 20. For this reason, the n-MOS transistor 22 is generally called an injection or polarisation transistor.

The detection circuit 18 also includes a controlled switch 24, mounted in series with the n-MOS transistor 22 and the microbolometric detector 20, for the transmission (synchronised with the other pixels) of the current Im that passes through this electronic circuit to the transmission column 12. This current Im is identical to the current Ids that passes through the n-MOS transistor 22 and the current Ibolo that passes through the microbolometric detector 20, such that its fluctuations contain the useful information supplied by the detector.

The current Ibolo is given by the following equation:

$$Ibolo = \frac{Vs}{Rbolo} = \frac{Vd - Vds}{Rbolo} = \frac{Vd}{Rbolo} - \frac{1}{Rbolo} \times Vds .$$

where Vs is the voltage of the source of the n-MOS transistor 22, Vd is the drain voltage, Vds is the drain-to-source voltage, and Rbolo is the resistance of the microbolometric detector 20.

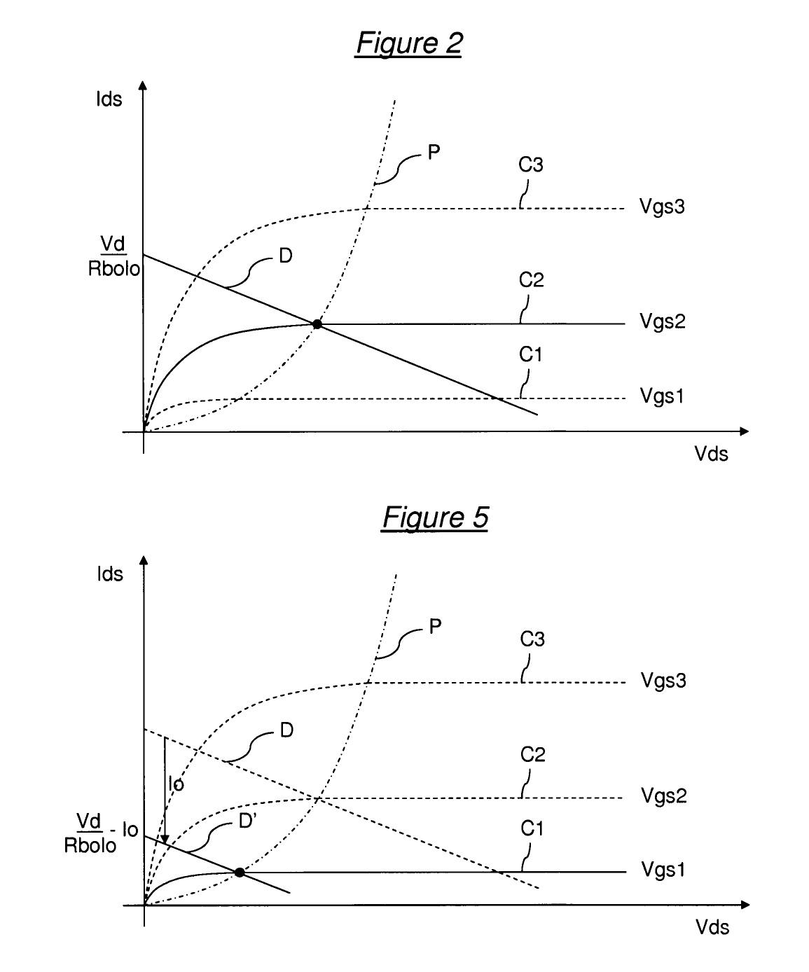

This gives a current/voltage characteristic represented by a downward-sloping line D in FIG. 2.

In addition, the current/voltage characteristics that can be obtained at the terminals of the n-MOS transistor 22 are based on the voltage Vgs between its gate and its source and are illustrated in FIG. 2 by three specific curves C1, C2, and C3 relative to three specific values Vgs1, Vgs2, and Vgs3 that the voltage Vgs can take.

In a known manner, these current/voltage characteristics that depend on the voltage Vgs each comprise a first part, called the resistive mode of the transistor in question, in which the intensity of the current Ids grows with the voltage Vds as Vds remains less than (Vgs−Vt), where Vt is a threshold voltage characteristic of the transistor in question, and a second part, called the saturated mode, in which the intensity of the current Ids remains relatively constant for values of Vds greater than (Vgs−Vt).

At the saturation limit, between these two modes, the current Ids is given by the following equation:

$$Ids = \frac{W}{L} \times \frac{{μ}_{m} {C}_{ox}}{2} \times {Vds}^{2} .$$

where W and L are the channel width and length of the transistor, μₙ is the electron mobility (majority carriers of the n-channel), and Cₒₓ is the capacity per surface unit of the transistor.

The set of points of the current/voltage characteristics that depend on the voltage Vgs at the saturation limit is given by the parabolic curve P shown in FIG. 2.

For the detection circuit 18 to operate properly, the gate voltage Gdt of the n-MOS transistor 22 is chosen such that it operates at the saturation limit. Accordingly, the value of Ibolo=Ids=Im is given by the operating point at the intersection between the line D and the parabola P.

This current Im supplied by the detection circuit 18 to the transmission column 12, because it comes from the microbolometric detector 20, presents a high common mode around which there are slight fluctuations in the current representing fluctuations in the temperature. Yet these slight fluctuations are useful information. A baselining circuit 26 is therefore generally provided in a top of column circuit 28 to supply a baselining current Ieb designed to reproduce this common mode and to be transmitted to the transmission column 12. In this manner, the current Ieb can be cut away from the current Im, thereby removing the common mode from the current Im in order to keep only the useful part.

The baselining circuit 26 generally includes a thermal microbolometric detector 30 connected in series to a MOS field-effect transistor 32, more specifically a p-type transistor in the example in FIG. 1. The terminal of the thermal microbolometric detector 30 that is not connected to the p-MOS transistor 32 is set to a voltage Veb, while the p-MOS transistor 32 is subjected to a gate voltage Geb. By “thermal microbolometric detector”, this means a microbolometric detector whose resistance is constant and independent of the received radiation.

Degradations affect the signal to be viewed. They are due, on the one hand, to the bolometric detector itself and, on the other hand, to the other electronic elements, including the injection transistor 22 and the components of the processing module 14. Therefore, there is a bolometric noise, on the one hand, and an electronic noise, on the other hand, that disturb the signal to be processed. These disturbances are particularly appreciable when the bolometric detector is at a low mean bolometric resistance.

It is observed, indeed, that the decrease in the mean bolometric resistance results in a decrease in the injection efficiency of the voltage polarisation transistor 22. Because of this decrease in efficiency, the transistor 22 does a poorer job of transmitting the current supplied by the microbolometric detector 20.

But the main phenomenon is the increase in current noise. If the mean bolometric resistance decreases, it is shown that the current noise caused by the microbolometric detector 20 decreases, but the current noise caused by the voltage polarisation transistor 22 increases more significantly due to the increase in the current passing through it.

A known solution for reducing the current noise caused by the voltage polarisation transistor 22 is to increase its size. It is shown that the larger the transistor, the less noisy it is.

However, changing the dimensions of the components is a delicate task, particularly in the field of imaging. The detection device is indeed usually comprised of a pixel array, such that the size of all components within a pixel is limited by the size of the pixel. Some components that are shared by multiple pixels, however, may be placed outside of the array, at the top or bottom of the column and/or row. There is then no longer any constraint on their size.

In the specific case of the voltage polarisation transistor 22, it is connected in series to the microbolometric detector 20 and close to it, even within the pixel 10. It is therefore limited in size because it is within the pixel.

It is possible to increase its size, however, provided that it is to make it shared by multiple pixels, but the overall architecture must then be completely reworked. Moreover, this sharing of the voltage polarisation transistor 22 between multiple pixels provides additional constraints on the operation of the detection device. Some infrared imagers advantageously work according to a scanning mode described as “rolling shutter”, by which several consecutive rows can be acquired at the same time. It is then no longer possible for this scanning mode to be used with large voltage polarisation transistors shared by multiple pixels.

The solution involving increasing the size of the voltage polarisation transistor 22 is therefore not optimal for resolving the aforementioned problem of overall performance.

It may therefore be desirable to provide a device for detecting electromagnetic radiation that can at least partially overcome the aforementioned problems and constraints without having to fall back on such a solution.

The invention therefore relates to a device for detecting electromagnetic radiation comprising at least one pixel for detecting a radiation and for providing an electric current representative of this detected radiation, the pixel comprising a detection circuit including a bolometric detector connected in series with voltage polarisation means, this device further comprising a current polarisation circuit of the bolometric detector, different from the detection circuit, connected to the bolometric detector at one point in the detection circuit located between the bolometric detector and the voltage polarisation means.

Therefore, this current polarisation of the bolometric detector, independent of the detection circuit and operating upstream of the voltage polarisation means, provides current needed by the bolometric detector to function optimally while decreasing, by application of Kirchoff's Current Law, the current flowing downstream of the current polarisation circuit. As a result, the current noise generated downstream of the current polarisation circuit is decreased, without needing large components.

It is also noted that this current polarisation can also serve to at least partially offset the common mode of the current supplied by the bolometric detector, thereby fulfilling a baselining function carried out upstream of the voltage polarisation means. If it is possible to fully offset the common mode, this new architecture can even dispense with the usual baselining structure at the top of the column.

This new architecture therefore fulfils the dual function of reducing the aforementioned electronic noise and upstream baselining, all without needing to resize the components and without needing to change the overall architecture of the array.

Optionally, the current polarisation circuit comprises a MOS field-effect transistor mounted as a current source.

Also optionally, the voltage polarisation means comprise a MOS field-effect transistor mounted as a voltage generator.

Also optionally, the MOS transistor of the current polarisation circuit and the MOS transistor of the voltage polarisation means are of different, n or p, types.

Also optionally, the MOS transistor of the voltage polarisation means is a p-type transistor. The p-MOS transistors are less noisy than n-MOS transistors such that it is advantageous that this is the MOS transistor of the voltage polarisation means rather than the MOS transistor of the current polarisation circuit, which is a p-MOS transistor.

Also optionally, the current polarisation circuit includes a thermal bolometer mounted in series with current polarisation means. In this case, the current polarisation circuit further carries out optimal baselining, which allows it to fully dispose of traditional baselining circuits.

Also optionally, the current polarisation circuit is located in the detection pixel. Its compact size effectively allows it to integrate into the pixel, despite the pixel's small size.

Also optionally, a detection device according to the invention may comprise a pixel array arranged in rows and columns and a current polarisation circuit for each column, shared by all pixels in the column and located at the top of the column. The result is a space savings.

Also optionally, the bolometric detector is an uncooled microbolometer. This type of bolometer is particularly well suited for the proposed architecture, especially when it has a low mean bolometric resistance.

Finally, the invention also related to the use of a detection device such as defined above for detecting infrared radiation.

The invention will be better understood using the following description, given purely as an example and referring to the accompanying drawings, in which:

FIG. 1, already described, schematically shows the overall structure of an electromagnetic radiation detection device in the prior art,

FIG. 2, already described, diagrammatically illustrates a current/voltage characteristic that highlights an operating point of a pixel of the device in FIG. 1,

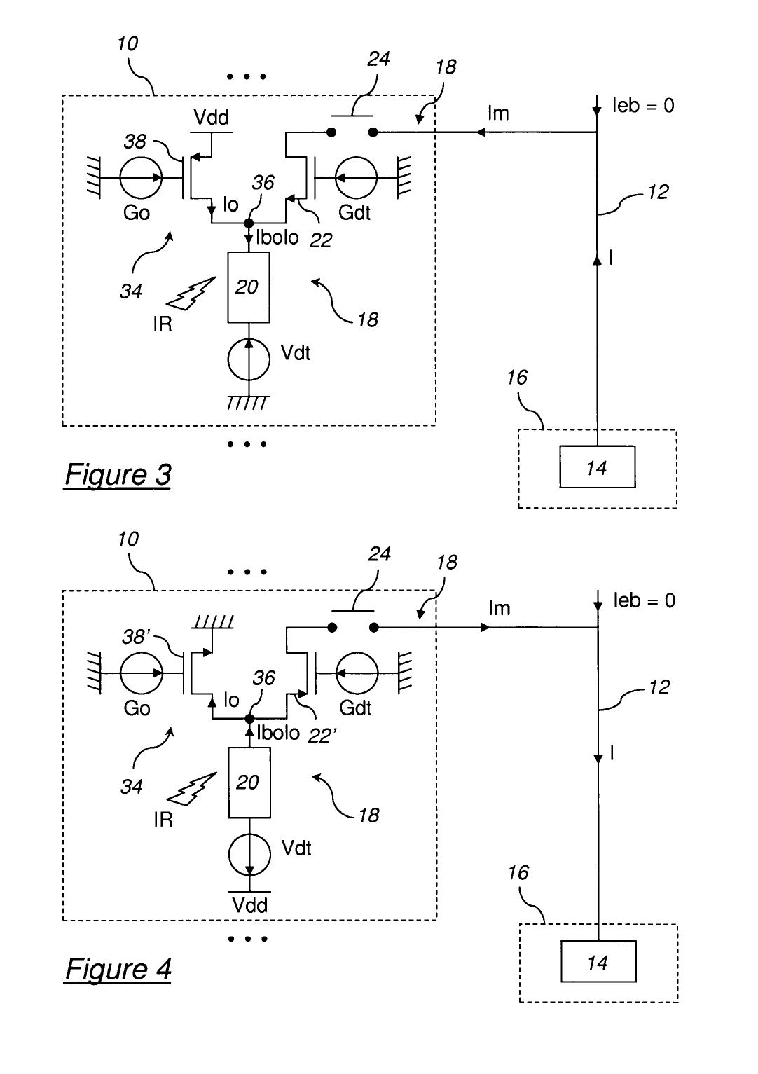

FIGS. 3 and 4 schematically show the overall structure of an electromagnetic radiation detection device according to first and second embodiments of the invention,

FIG. 5 diagrammatically illustrates a current/voltage characteristic that highlights an operating point of a pixel of the device in FIG. 3 or 4,

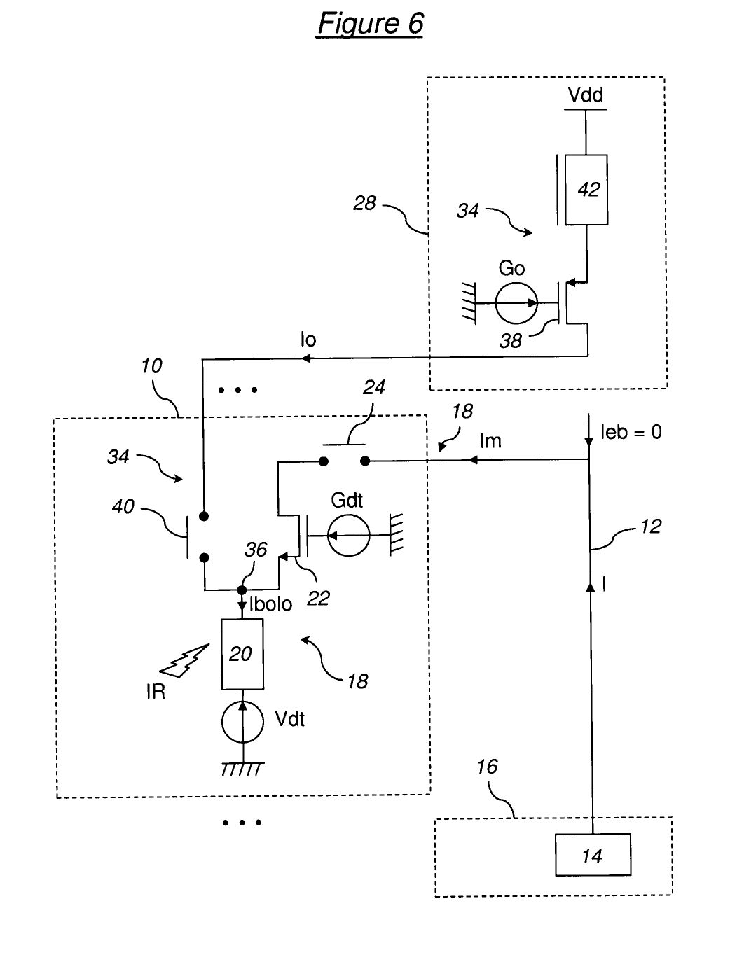

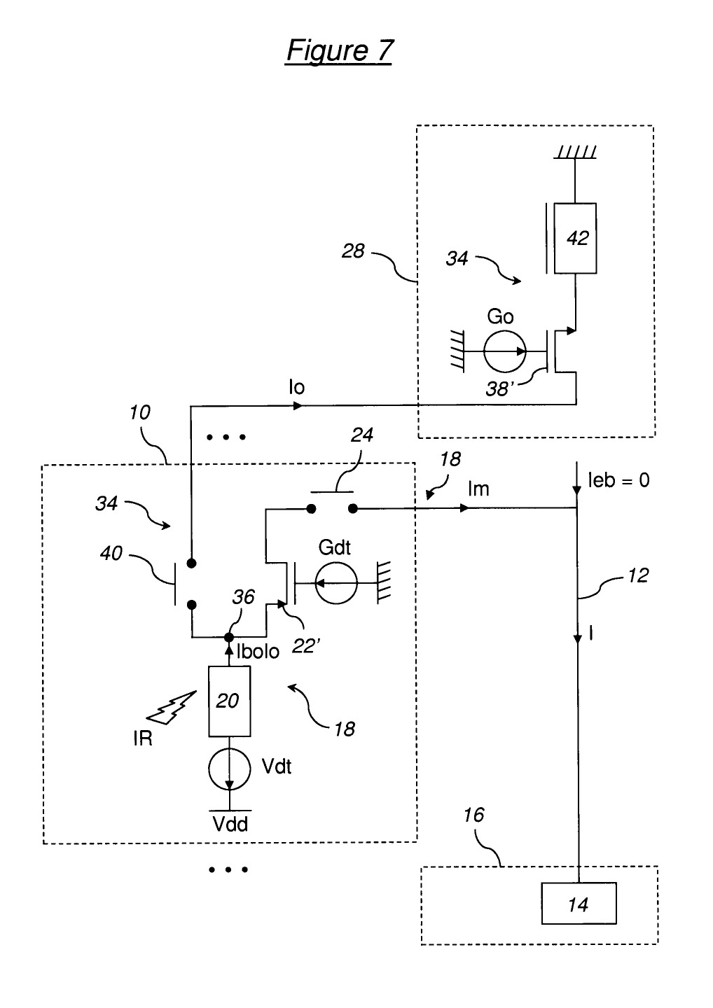

FIGS. 6 and 7 schematically show the overall structure of an electromagnetic radiation detection device according to third and fourth embodiments of the invention.

The electromagnetic radiation detection device shown in FIG. 3 has a number of elements that are identical to those in the prior art described earlier. These elements therefore have the same references.

Therefore, although this device includes a pixel array arranged in rows and columns, only one pixel 10 and one transmission column 12 are shown, for the sake of clarity.

This transmission column 12 is connected to a module 14 for processing electric currents in a bottom of column circuit 16.

The pixel 10 comprises an electronic circuit 18 for detecting electromagnetic radiation. This detection circuit 18 includes, mounted in series, a bolometric detector 20, an n-MOS transistor 22 for voltage polarisation of the bolometric detector 20 and a controlled switch 24 for the synchronised transmission of the current Im that passes through this electronic circuit 18 to the transmission column 12. This current Im is identical to the current Ids that passes through the transistor n-MOS 22, but unlike the device in FIG. 1, it is not identical to the Ibolo current that passes through the bolometric detector 20.

Indeed, the pixel 10 also comprises a circuit 34 for current polarisation of the bolometric detector 20, different from the detection circuit 18, connected to the bolometric detector 20 at one point 36 in the detection circuit 18 located between the bolometric detector 20 and the n-MOS voltage polarisation transistor 22.

The current polarisation circuit 34 has a p-MOS transistor 38 mounted as a current source. In other words, its source is powered at a potential Vdd, and its gate is controlled by an adjustable voltage Go to provide a current with a predetermined intensity Io.

By application of Kirchoff's Current Law at the node 36, a relationship is established between the three currents, Io, Ids=Im, and Ibolo: Ids=Ibolo−Io.

Therefore, when the bolometric detector 20 is, for example, a microbolometric detector that must operate with a mean current of around I μA, it is possible to adjust Go so that Io is around I−ε μA (ε being low compared to I), this value advantageously corresponding to the common mode of the current supplied by the microbolometric detector 20. A current Ids=Im is thus obtained at the terminals of the n-MOS voltage polarisation transistor 22 near ε μA, which makes it possible to substantially decrease the current noise generated by this transistor. Advantageously, if this current Ids=Im is cleared of the common mode, it only contains the useful information to supply to the processing module 14.

Moreover, for the microbolometric detector 20, optimal operation is obtained if the voltage between its terminals is close to a predetermined value Vo V. This value can be obtained by an adjustment thanks to the n-MOS transistor 22 mounted as a voltage generator. More specifically, it is obtained by setting the potential of one of the terminals of the microbolometric detector 20 to a value Vdt and by setting the potential of the other of its terminals, at point 36, by adjusting the gate voltage Gdt of the voltage polarisation n-MOS transistor 22.

It will be noted that the presence of the voltage polarisation n-MOS transistor 22, preserved in the proposed architecture, allows the detection circuit 18 to have a floating voltage at the transistor's drain, which insulates the voltage of the pixel 10 from the other pixels in the array and generally avoids disturbing a pixel when reading another pixel.

It has been seen that the polarisation current Io is adjustable via the gate voltage Go of the p-MOS transistor 38. Similarly, the gate voltage Gdt of the n-MOS transistor 22 to some extent adjusts the current Ids=Im by polarising the voltage of the bolometric detector 20. Between them, the gate voltage of the two transistors 22 and 38 makes it possible to set the three mean currents of the three branches of the detection and current polarisation circuits: Io, Ibolo, and Ids=Im. In this manner, the right configuration can be found whereby the measuring current Im reaches an adequate value that is small enough to make the n-MOS transistor 22 less noisy and large enough to be able to contain all of the current changes related to temperature changes in the detected scene.

The current Ibolo is still given by the following equation:

$$Ibolo = \frac{Vs}{Rbolo} = \frac{Vd - Vds}{Rbolo} = \frac{Vd}{Rbolo} - \frac{1}{Rbolo} \times Vds .$$

However, Ids=Ibolo−Io, hence:

$$Ids = \frac{Vd}{Rbolo} - Io - \frac{1}{Rbolo} \times Vds .$$

This gives a current/voltage characteristic represented by the downward-sloping line D′ in FIG. 5. It is parallel to the line D, but shifted from Io to the negative ordinates.

For the detection circuit 18 to operate properly, the gate voltage of the n-MOS transistor 22 is chosen such that it operates at the saturation limit. Accordingly, the value of Im=Ids=Ibolo−Io is given by the operating point at the intersection between the line D′ and the parabola P defined earlier. The current Im at the operating point is greatly reduced compared to the current Im obtained in the device in FIG. 1.

This current Im supplied by the detection circuit 18 to the transmission column 12 can no longer even support common mode if the value of Io is well chosen. It then contains no more than the slight changes that make up useful information. The baselining circuit 26, generally provided at the top of the column as indicated in FIG. 1, is no longer necessary in this case. The architecture of the detection device is simplified.

Unlike the architecture shown in reference to FIG. 1, where there was only one voltage polarisation of the bolometric detector 20 via the injection transistor, we must consider two different effects in the architecture presented in reference to FIG. 3.

At a first order, the bolometric detector 20 undergoes a current polarisation via the current polarisation circuit 34. This corresponds, as pictured, to a rough adjustment of the current in the bolometric detector 20.

At a second order, the voltage polarisation n-MOS transistor 22 is involved, in its operation at the saturation limit, in determining, via its gate voltage Gdt, the new operating point for the detection circuit 18. As shown in FIG. 5, this operating point depends on the polarisation current Io from the current polarisation circuit 34, determines the mean current at the terminals of the n-MOS transistor 22, and accordingly sets its source voltage and thus the voltage of the terminals of the bolometric detector 20.

The n-MOS transistor 22 therefore fulfils the same function of voltage polarisation of the bolometric detector 20 as in the architecture in FIG. 1, but this voltage polarisation function only comes into play at a second order. The action on the gate voltage Gdt of this transistor corresponds, as pictured, to a finer adjustment of the current in the bolometric detector 20 and of the balanced state.

These two effects, the current polarisation at the first order and the voltage polarisation at the second order, cause the detection circuit 18 to converge toward its operating point. Ultimately, the optimal operating conditions are met. On the one hand, the current passing through the bolometric detector 20 is high enough, as the sum of the polarisation current lo and the measuring current Im=Ids, and on the other hand the measuring current is low enough to decrease the current noise generated by the n-MOS transistor 22, yet high enough to contain all of the useful information, all without resizing the n-MOS transistor 22.

It is also observed that the voltage polarisation n-MOS transistor 22 and the current polarisation transistor 38 are MOS field-effect transistors of different, n or p, types. In this instance, the transistor 22 is an n-type transistor and the transistor 38 is a p-type transistor. But the reverse is also possible, with a slight reorganisation in the architecture. A second embodiment of the invention proposing this reorganisation is illustrated in FIG. 4.

In this figure, the pixel 10 comprises a p-type voltage polarisation transistor 22′ and an n-type voltage polarisation transistor 38′. The architecture of the pixel 10 is also slightly reorganised as follows: the source of the current polarisation transistor 38′ is connected to the ground, while the terminal of the bolometric detector 20, initially set to the potential Vdt is now set to the potential Vdd−Vdt. The currents Io, Im, and Ibolo are also reversed, which has no effect on the equations and the operating point indicated earlier.

Simply note that a p-MOS type transistor is generally less noisy than an n-MOS transistor. Accordingly, it is more advantageous to use a p-MOS transistor as an injection transistor (i.e. voltage polarisation transistor). In this respect, the second embodiment therefore provides better results than the first embodiment.

Moreover, given that the current polarisation circuit 34 also carries out an at least partial baselining function, it is not essential for it to be integrated into the pixel 10. Therefore, FIG. 6 illustrates a third embodiment of the invention, in which the current polarisation circuit 34, although still connected to the point 36 inside the pixel 10, is held in the top of column circuit 28. A current polarisation circuit can thus be located at the top of each column of the pixel array of the detection device.

In accordance with this third embodiment, which represents a variant of the first embodiment, the current polarisation circuit 34 also comprises a controlled switch 40, operated as the controlled switch 24, to synchronise the pixels of the array in their capture and transmission of information.

As in the first embodiment described earlier, the current polarisation circuit 34 may include only one transistor mounted as a current source, which means that the completed baselining thus would correspond to a simple subtraction of a constant value set to Io and considered to represent the common mode, regardless of the operating temperature. This would therefore not be optimal baselining since it is known that, when the temperature increases, any bolometric detector undergoes a temperature increase, which decreases the mean value of its resistance and increases the common mode of the current passing through it.

To accommodate this phenomenon, optionally, a thermal bolometric detector 42 can be inserted between the potential Vdd and the source of the current polarisation p-MOS transistor 38. This thermal bolometric detector 42 also undergoes a temperature increase without become subject to sudden changes in the scene, so as to optimise the baselining function of the current polarisation circuit 34. In this manner, the baselining function described in reference to FIG. 1 is fully reproduced here.

Such a thermal bolometric detector could also have been integrated into each pixel of the first embodiment, but this option is advantageously implemented when the current polarisation circuit 34 is held at the top of the column 28.

Finally, as earlier, it is also possible to reverse the types of the two MOS field-effect transistors used, with a slight reorganisation in the architecture. A fourth embodiment of the invention proposing this reorganisation is illustrated in FIG. 7.

In this figure, the pixel 10 comprises a p-type voltage polarisation transistor 22′, and the current polarisation circuit 34, held at the top of the column 28, comprises an n-type current polarisation transistor 38′. The architecture of the pixel 10 is also reorganised as follows: the terminal of the bolometric detector 20 initially set to the potential Vdt is now set to the potential Vdd−Vdt. The architecture of the top of column circuit 28 is reorganised as follows: the terminal of the thermal bolometric detector 42 that is not connected to the source of the current polarisation transistor 38′ is connected to the ground. The currents Io, Im, and Ibolo are also reversed, which has no effect on the equations and the operating point indicated earlier.

Again, since it is more advantageous to use a p-MOS transistor as an injection transistor (i.e. voltage polarisation transistor), the fourth embodiment provides better results than the third embodiment in this regard.

Clearly, an electromagnetic radiation detection device with a bolometric detector such as one of those described earlier, in accordance with embodiments of the invention, can decrease electronic noise relative to bolometric noise, without having to also increase the size of the electronic components associated to the bolometric detectors.

Thus, compared measurements taken on the devices in FIGS. 1 and 3, for example, show that the proportion of the electronic noise in the overall noise is greatly reduced. The electronic noise that was predominant compared to the bolometric noise is relatively less. The signal/noise ratio is improved, ultimately providing a better quality image with greater resolution.

It also appears that such a device is easy to implement, without a major complication or reorganisation of the initial architecture. The overall architecture of the array does not need to be revised. Ultimately, there is no equipment necessarily added to the original architecture either. The transistor added for current polarisation also fulfils a baselining role, at least partially. It can therefore be placed at the top of the column to replace the original baselining structure. When it is used in series with a thermal bolometric detector, it even optimally fulfils the baselining function.

In addition, since it is no longer necessary to increase the size of the electronic components contained in each pixel, this makes it possible to avoid sharing these components between multiple pixels. The “rolling shutter” scanning mode is therefore still possible.

In conclusion, the proposed architecture can improve the performance of imagers for microbolometric detectors.

Such imagers are developed for the industrial production of higher performing infrared cameras in terms of produced image quality.

1-10. (canceled)

11. A device for detecting electromagnetic radiation comprising:
pixels for detecting a radiation, each for providing an electric current representative of the detected radiation;
a column to which the pixels are connected and for transmitting the electric currents provided by the pixels;
an electrical module, to which the transmission column is connected, for processing the electric currents provided by the pixels, each pixel comprising a detection circuit including a bolometric detector connected in series to voltage polarization means of the bolometric detector for adjusting the electric current supplied to the processing module by the transmission column; and
a current polarization circuit of the bolometric detector for adjusting the electric current supplied to the processing electrical module by the transmission column, the current polarization circuit being different from the detection circuit and connected to the bolometric detector at one point in the detection circuit located between the bolometric detector and the voltage polarization means.

12. A detection device according to claim 11, in which the current polarization circuit comprises a MOS field-effect transistor mounted as a current source.

13. A detection device according to claim 12, in which the voltage polarization means comprises a MOS field-effect transistor mounted as a voltage generator.

14. A detection device according to claim 13, in which the MOS transistor of the current polarization circuit and the MOS transistor of the voltage polarization means are of different, n or p, types.

15. A detection device according to claim 14, in which the MOS transistor of the voltage polarization means is a p-type transistor.

16. A detection device according to claim 11, in which the current polarization circuit comprises a thermal bolometer mounted in series with current polarization means.

17. A detection device according to claim 11, in which the current polarization circuit is held in the detection pixel.

18. A detection device according to claim 11, comprising a pixel array arranged in rows and columns and a current polarization circuit for each column, shared by all pixels in the column and held at the top of the column.

19. A detection device according to claim 11, in which the bolometric detector is an uncooled microbolometer.

20. A use of a detection device according claim 11 for detecting infrared radiation.
